(19) United States
(12) Patent Application Publication
(10) Pub. No.: US 2017/0207625 A1
(43) Pub. Date: Jul. 20, 2017

(54) SYSTEMS AND METHODS FOR EFFICIENT TRANSMISSION OF POWER OVER A DISTANCE

(71) Applicant: Hiatt Bean, Chantilly, VA (US)

(72) Inventor: Hiatt Bean, Chantilly, VA (US)

(21) Appl. No.: 15/342,673

(22) Filed: Nov. 3, 2016

Related U.S. Application Data
(63) Continuation of application No. 13/546,752, filed on Jul. 11, 2012, now abandoned.
(60) Provisional application No. 61/506,965, filed on Jul. 12, 2011.

(51) Int. Cl. H02J 3/00; G05F 5/00; H01R 24/20; H01R 24/28; H05K 5/02; H05K 5/00

(52) U.S. Cl. CPC H02J 3/00; H05K 5/023; H05K 5/0086; H01R 24/20; H05K 5/0017; H01R 24/28; G05F 5/00; H01R 2103/00

(57) ABSTRACT

Various methods and systems for efficiently transmitting electric energy or power over a distance are disclosed. In one example embodiment, a low loss electric energy extension cord includes a step-up transformer configured to step up a potential of electric energy received at the step-up transformer, a transmission line coupled to receive, at a first end thereof, the stepped-up potential electric energy from the step-up transformer, and a step-down transformer coupled to receive the stepped-up potential electric energy from a second end of the transmission line and configured to step down the potential of the stepped-up potential electric energy. The low loss electric energy extension cord comprising the step-up transformer, the transmission line, and the step-down transformer is portable.

### CROSS-REFERENCE TO RELATED APPLICATION

This application is a continuation of U.S. patent application Ser. No. 13/546,752, filed Jul. 11, 2012, which claims priority from and the benefit of United States Patent Application Ser. No. 61/506,965 filed on Jul. 12, 2011 and entitled “SYSTEMS AND METHODS FOR EFFICIENT TRANMISSION OF POWER OVER A DISTANCE,” which application is hereby expressly incorporated herein in its entirety.

### BACKGROUND

Embodiments of this invention generally relate to systems and methods for efficient transmission of power or electric energy over a distance. More specifically, embodiments of this invention reduce power loss near the point of energy consumption.

When electric energy is transmitted over a transmission line, some energy is inevitably lost due to the resistance of the transmission lines. The energy is simply converted to heat. Using a low resistance and low gauge materials for transmission lines can reduce the amount of energy lost. However, at a certain point the cost of using low resistance and low gauge material becomes too prohibitive.

Reducing the amount of current in the electric energy being transmitted can also reduce energy loss. The amount of energy lost is a second order exponential function of the amount of current in the electric energy being transmitted. Moreover, if a potential (i.e., voltage) level of the electric energy is increased, the amount of current can be proportionally decreased without reducing the amount of electric energy being transmitted. Thus, one technique currently used to reduce energy loss is to transmit electric energy from power generation sources, e.g., power plants, at an extremely high potential (e.g., 110 kiloVolts). Most if not all electric appliances and machines are designed to use electric energy at much lower potential levels (e.g., 110 volts in the U.S., 220 volts in other regions, such as Europe) to ensure safety. Therefore, at some point (or series of points) the high potential of the electric energy carried over transmission lines is stepped down to a safer, useable level. The final stepping down point is often at a large transformer on or near the premises of a building. However, electric energy must still be carried over substantial distances from the step-down transformer, resulting in substantial and wasteful losses of energy. This problem is particularly acute at sites, such as rural properties, where the electric energy must be distributed to locations that are remote from the step-down transformer.

### SUMMARY

In general, example embodiments of the invention relate to methods and systems for efficiently transmitting power or electric energy. In particular, the methods and systems reduce loss of energy in transmission lines that are proximate to a location of energy consumption.

In one example embodiment, a low loss electric energy extension cord includes a step-up transformer configured to step up a potential of electric energy received at the step-up transformer, a transmission line coupled to receive, at a first end thereof, the stepped-up potential electric energy from the step-up transformer, and a step-down transformer coupled to receive the stepped-up potential electric energy from a second end of the transmission line and configured to step down the potential of the stepped-up potential electric energy. The low loss electric energy extension cord comprising the step-up transformer, the transmission line, and the step-down transformer is portable.

In a second example embodiment, a system for transmitting electric energy over a distance includes a generator unconnected to any public-use power grid and configured to generate electric energy at a potential that is higher than a potential supplied by a power company to a wall socket. The system further includes a transmission line coupled to receive the high potential electric energy from the generator and configured to convey the high potential electric energy over a distance, and a step-down transformer coupled to receive the high potential electric energy from the transmission line and configured to step down the potential of the high potential electric energy.

In a third example embodiment, a portable system for receiving electric energy over a distance and distributing the received electric energy includes a step-down transformer coupled to receive electric energy from an external source and configured to step down a potential of the electric energy. The system further includes an electric socket coupled to receive the stepped-down electric energy and configured to supply the stepped-down electric energy to a plug when the plug is mated with the electric socket.

In a fourth example embodiment, a system for receiving electric energy over a distance and distributing the received electric energy includes a receptacle configured to receive a transmission line carrying electric energy from an external source and a step-down transformer coupled to receive the electric energy from the receptacle and configured to step down a potential of the electric energy. The system further includes an electric socket coupled to receive the stepped-down electric energy and configured to supply the stepped-down electric energy to a plug when the plug is mated with the electric socket, an interface configured to receive input from an operator regarding a potential level of the electric energy carried by the transmission line, and a controller configured to control a step-down level of the step-down transformer based at least in part on the potential level of the electric energy received from the external source.

In a fifth example embodiment, a system for receiving electric energy over a distance and distributing the received electric energy includes a plurality of receptacles, each of the receptacles being configured to receive a transmission line carrying electric energy from an external source, and a step-down transformer coupled to receive the electric energy from the receptacle and configured to step down the potential of the electric energy. A level by which the step-down transformer steps down the potential is dependent on which of the plurality of receptacles an operator selects to receive the transmission line. The system further includes an electric socket coupled to receive the stepped-down electric energy and configured to supply the stepped-down electric energy to a plug when the plug is mated with the electric socket.

In a sixth example embodiment, an electric socket includes a receptacle configured to receive a transmission line that originates from an electric distribution panel and a step-down transformer coupled to receive electric energy over the transmission line and configured to step down a potential of the received electric energy. The electric socket further includes a plug interface configured to supply the stepped-down electric energy to an electric machine when a plug of the electric machine is inserted into the plug interface.

In a seventh example embodiment, a method for providing electric energy from an electric socket to an electric machine includes 1) stepping up a potential of electric energy supplied by the electric socket by a step up amount, 2) transmitting the stepped-up potential electric energy over a transmission line, and 3) stepping down the stepped-up potential electric energy transmitted over the transmission line by a step down amount. A magnitude of the step up amount is the same as or greater than a magnitude of the step down amount.

In an eighth example embodiment, a method for providing electric energy from an electric distribution panel to an electric machine includes 1) supplying electric energy from an electric distribution panel to an electric socket, both the electric distribution panel and the electric socket being located at the same building, 2) stepping down the electric energy at the electric socket, and 3) consuming the stepped-down electric energy at an electric machine when the stepped-down electric energy is plugged into the socket and operated

Additional features of the invention will be set forth in the description which follows, and in part will be obvious from the description, or may be learned by the practice of the invention. The features of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 shows a low loss electric energy extension cord;

FIG. 2 shows an example system for efficiently transmitting electric energy from a generator;

FIG. 3 shows an example portable system for efficiently transmitting electric energy;

FIG. 4 shows an example system for efficiently transmitting electric energy received via a hard-wired connection;

FIG. 5 shows another example system for efficiently transmitting electric energy received via a hard-wired connection;

FIG. 6 shows an example system for efficiently transmitting electric energy between an electric distribution panel and various remote points in a building;

FIG. 7 shows an example method for providing electric energy from an electric socket to an electric machine; and

FIG. 8 shows an example method for providing electric energy from an electric distribution panel to an electric machine.

### DETAILED DESCRIPTION

Reference will now be made to the figures wherein like structures will be provided with like reference designations. It is understood that the figures are diagrammatic and schematic representations of presently preferred embodiments of the invention, and are not limiting of the present invention, nor are they necessarily drawn to scale.

Embodiments of the systems and methods described herein may provide, among other things, efficient transmission of electric energy (i.e., power or power signals) to distant points. An example system includes a step-down transformer in proximity to a location at which the electric energy is used. Accordingly, electric energy is transmitted at a high potential over transmission lines that previously carried low potential electric energy, thereby avoiding resistive loss that would otherwise occur.

### I. First Embodiment

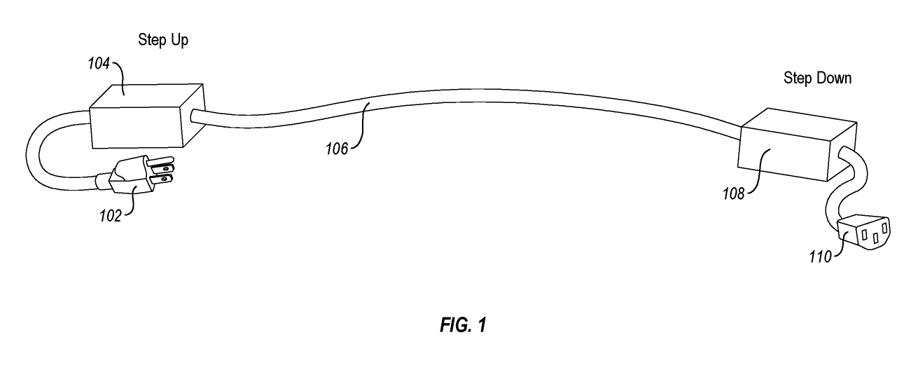

FIG. 1 shows a low loss electric energy extension cord 100. Extension cord 100 includes a male plug interface 102, a step-up transformer 104 coupled to male plug interface 102, a transmission line or cord 106 coupled to step-up transformer 104, a step-down transformer 108 coupled to transmission line 106, and a female plug interface 110 coupled to step-down transformer 108. Male plug interface 102 may be a standard 110 volt or 220 volt plug interface that can plug into a wall socket (i.e., outlet) to receive electric energy from the socket and supply it to step-up transformer 108. Step-up transformer 108 may be configured to step up a potential of the electric energy in preparation for its transmission over transmission line 106. By stepping up the potential before transmission, a current in the electric energy is proportionally reduced and, consequently, line loss is at least partially prevented. Step-down transformer 108 steps down the potential in the transmitted electric energy back to a useable level. For example, step-down transformer 108 may step down the potential by an amount equal to or less than an amount by which the potential was stepped up by step-up transformer 104. In one embodiment of extension cord 100, some or all of the foregoing components (102-110) of extension cord 100 are formed together as an integral system. In another embodiment, certain components may be detachable from the others. For example, transmission line 106 may be detachable from one or both of transformers 104 and 108.

In some embodiments, male and female plug interfaces 102, 110 may be omitted or replaced with a different type of interface. For example, if a non-standard interface is required at either end for a special-purpose use of extension cord 100, one or both of male and female plug interfaces 102, 110 may be omitted or replaced with a suitable interface. Moreover, system 100 may include a circuit breaker located, e.g., near or within a housing of step-down transformer 108 to guard against excessive loads.

### II. Second Embodiment

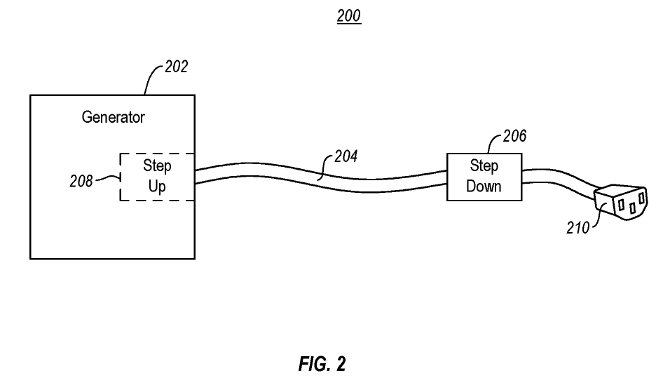

FIG. 2 shows a system 200 for efficiently transmitting electric energy. System 200 includes a generator 202, a transmission line 204, and a step-down transformer 206. Electric energy is supplied from generator 202 to step-down transformer 206 located remotely from generator 202 over transmission line 204. Generator 202 may be configured to supply the electric energy at a high potential to prevent line loss or generator 202 may include or be coupled to an optionally present step-up transformer 208 interposed between the source of electric energy and transmission line 204. Step-down transformer 206 is configured to receive the high potential electric energy and step it down to a level at which it can be used (e.g., 110V). Also optionally included in system 200 is a plug receptacle 210 coupled to an output of or integrated with step-down transformer 206. Plug receptacle 210 is configured to receive a standard plug of an electric machine or appliance (also called “device” herein) and supply the stepped-down electric energy to the plug. Moreover, system 200 may include a circuit breaker located, e.g., near or withing a housing of step-down transformer 206 to guard against excessive loads.

Generator 202 may be a generator that is unconnected to any public-use grid or capable of being used in an unconnected configuration at a home, recreational vehicle, houseboat, or any other building, vehicle, or craft. For example, generator 202 may be a stand-alone generator powered by gasoline (or other petroleum product). Alternatively, generator 202 may be a solar panel generator configured to generate electric energy using solar energy, a wind turbine generator configured to generate electric energy using wind. Moreover, in one embodiment, generator 202 may be a nuclear reactor configured to generate electric energy using a nuclear reaction (e.g., on a submarine or the like).

In one embodiment of system 200, transmission line 204 may be detachable from generator 202 to facilitate connection of transmission lines of different lengths. In a system according to this embodiment, step-down transformer 206 may include a user interface, which may optionally including a display. A controller that controls the user interface may be programmed to receive input variables from a user or operator via the user interface. The input variables may include one or more of the following: a potential level of electric energy at the output of generator 202, a length of transmission line 204, a gauge number (e.g., an AWG gauge number) of transmission line 204, a voltage level required by an electric machine or device to plugged into plug receptacle 210, a current level required by a load (e.g., an electric machine or device) to plugged into plug receptacle 210. In certain alternative embodiments, one or more of the foregoing input variables may be predetermined.

Based on one or more of the input variables received from the operator, the controller of step-down transformer 206 may calculate a range of acceptable transmission line lengths that can be used. For example, to meet the required voltage and current levels of the load used with system 200, the controller may determine that the transmission line length should be no more than 200 feet. Moreover, for transmission line lengths over which a standard system lacking the efficient power transmission aspects of system 200 would have been able to provide sufficient power, the controller may also calculate an amount of power savings realized by using system 200 versus the standard system. In addition, or alternatively, the controller may also calculate how much additional line length is made available by use of system 200 versus the standard system. The determinations and calculations made by the controller may be based on a predetermined gauge number (e.g., 12 gauge) associated with transmission line 204, a gauge number that is input by an operator, or a set of two or more different gauge numbers to provide a comparison for the operator's evaluation. A display, optionally included as part the aforementioned user interface, may display the foregoing determinations and calculations to the operator.

The controller of step-down transformer 206 may also run one or more self-diagnostic tests to determine whether the length of transmission line 204 is within an acceptable range or to verify it matches a length input by the operator. Another test may be run to determine a voltage level (or range of voltage levels) available for use at the load given a diagnosed transmission line length and a required load current input by the operator. Another test may be run to verify whether a potential level of electric energy at the output of generator 202 is adequate or is consistent with the potential level input by the operator. Results of the one or more tests may be output on the display. In addition, or alternatively, a simple indicator, such as a green LED, may light up to indicate that the system is ready and that any tests that have been conducted are successful.

### III. Third Embodiment

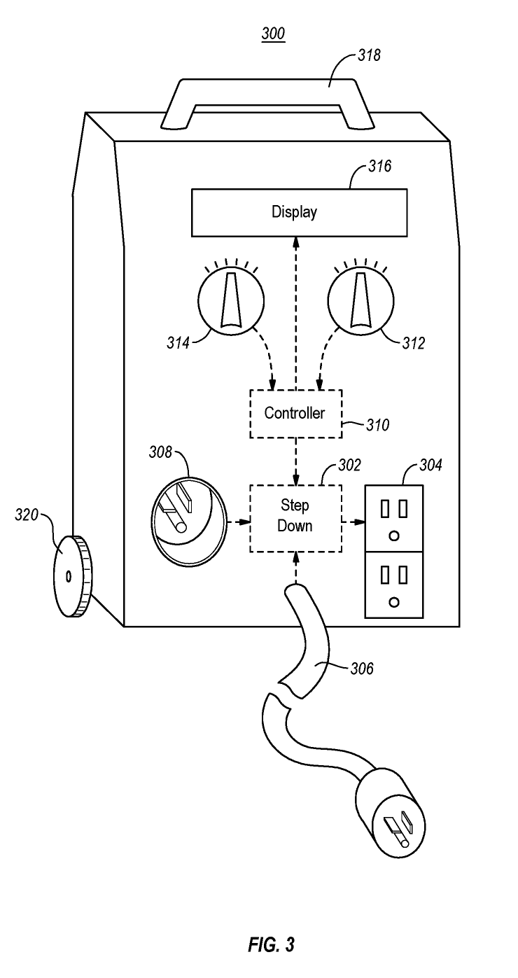

FIG. 3 shows a portable system or apparatus 300 that receives high potential electric energy from an external source over a distance, steps down the potential of the electric energy, and distributes the received stepped-down electric energy to one or more electric machines or devices capable of being plugged into the system. One example use for system 300 is to supply electric energy to electric machines or devices an outdoor environment, e.g., a construction site or rural property or in any environment in which electric energy must be transmitted over substantial distances. For example, an outdoor lighting system often uses numerous, long extension cords to convey electric energy from a distant central source to all of the lights. System 300 may receive the electric energy from the distant central source at a high potential and distribute the electric energy to each light at the appropriate potential, thereby reducing line losses and saving energy.

System 300 includes a step-down transformer 302 that is coupled to receive high potential electric energy from the external source and steps down the potential of the electric energy. In one embodiment, the external source may include a commonly used step-down transformer that is normally designed to provide electric energy at 110V but is instead reconfigured or designated to provide electric energy at 240 volts or an even higher potential level. System 300 may also include one or more electric sockets 304 that receive the stepped-down electric energy and supply the stepped-down electric energy to a plug of an electric machine or device when the plug is mated with electric socket 304. Step-down transformer 302 may step down the potential to a standard use level (e.g., 110 volts) and electric sockets 304 may be standard electric sockets.

System 300 may include a high potential transmission line (i.e., cord) 306 integrated with and extending from system 300. A remote end of high potential cord 306 may be configured with a non-standard interface, such as the one shown in FIG. 3. Consequently, high potential cord 306 is keyed to mate with only a high potential electric energy source or socket. Alternatively, or in addition, system 300 is equipped with a high potential socket 308 that is configured to receive an end of an electric cord that is keyed similar to high potential extension cord 306. Thus, system 300 may receive high potential electric energy via either high potential cord 306 or high potential socket 308 depending on which one the system is equipped with or which one an operator selects (if equipped with both). Moreover, in embodiments that are equipped with high potential socket 308, the socket may be a recessed male interface that mates with a female end of an extension cord, thereby avoiding the unsafe exposure of live male contacts on the extension cord. To further ensure safety, a sensor may be included at the source of electric energy to detect when high potential cord 306 or high potential socket 308 is securely connected to receive electric energy before providing the electric energy.

System 300 may also include a controller 310 that controls an amount by which step-down transformer 302 steps down the potential of received electric energy. Controller 310 receives input from an interface and, based on the input, determines or calculates an amount by which step-down transformer 302 steps down the potential of received electric energy. The interface may include any suitable user-input device, such as one or more manually controllable selectors (i.e., knobs or dials), a keypad, one or more switches, or the like. For example, in the embodiment shown in FIG. 3, the interface includes a first selector 312 and a second selector 314. First selector 312 may receive input regarding a transmission line length over which electric energy is to be supplied by system 300 via a transmission line or cord plugged into electric socket 304. For example, first selector 312 may provide a number of options, such as 50 feet, 100 feet, 200 feet, etc., which may be selected by turning first selector 312 to a desired option. (Alternatively, the available selections may be ranges of line lengths, e.g., 10 to 50 feet, 50 to 100 feet, 100 to 200 feet, etc.) Second selector 314 may receive input regarding the potential of the electric energy being received by system 300. Alternatively, system 300 may be equipped with a sensor that automatically senses the potential.

Based at least in part on the selected line length and/or the selected (or sensed) potential of received electric energy, controller 310 determines an appropriate amount by which step-down transformer 302 should step down the received high potential electric energy. In one embodiment, step-down transformer 303 is controlled to step down the potential by an amount that will ensure that the potential of the electric energy at a remote end of a cord over which the stepped-down electric energy is transmitted from system 300 is between maximum and minimum thresholds (e.g., between 115 and 105 volts). For example, if the line length of a cord being used is relatively short, step-down transformer may be controlled to step the potential down by a larger amount than if a relatively long line length is being used. The longer the line length, the greater the amount of degradation in potential is expected. Therefore step-down transformer 302 is controlled by controller 310 to account for the expected amount of potential degradation. Moreover, the higher the potential of the received electric energy, the more the potential needs to be stepped down to be useable by standard electric machines and devices. Thus, the higher the received potential, the greater the amount by which step-down transformer 302 is controlled to step down the potential of the received electric energy.

Certain embodiments of system 300 may also include a display 316 or other output device that provides signals and information to an operator information, such as diagnostic and/or safety information. For example, controller 310 may be programmed similar to the controller of the alternative embodiment of system 200 described above to determine, e.g., a range of acceptable transmission line lengths, power savings realized, additional line length available, and/or to run one or more diagnostic tests, as described above with reference to system 200. Also, system 300 may include a handle 318 and/or wheels 320 to facilitate portability, and may include a circuit breaker located, e.g., between step-down transformer 302 and electric socket 304, to guard against excessive loads.

### IV. Fourth Embodiment

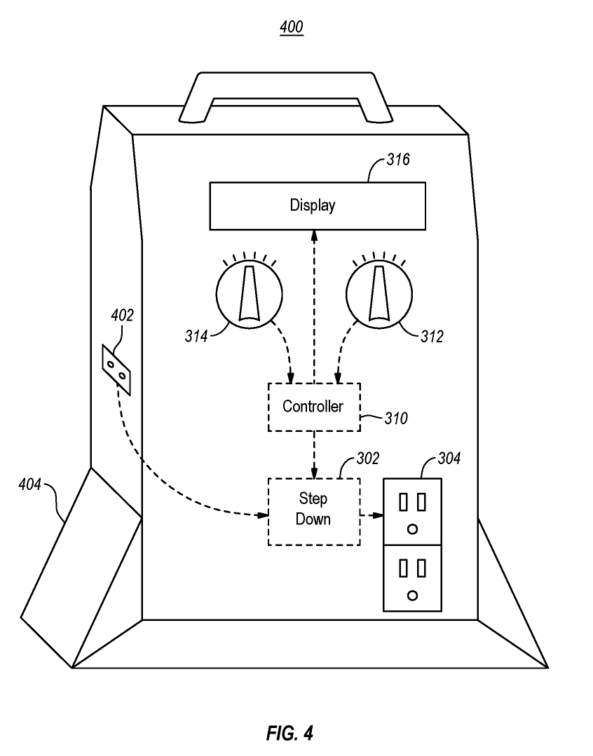

FIG. 4 shows another system 400 that may be used instead of or in addition to system 300 to receive and step down high potential electric energy and distribute the stepped-down the electric energy to electric machines or devices. System 400 differs from system 300 in that it is less portable and/or receives the high potential electric energy through a different interface thereof. More particularly, instead of being equipped with high potential cord 306 or high potential socket 308, system 400 is equipped with a receptacle 402 that receives one or more bare ends of corresponding transmission lines. Thus, step-down transformer 302 steps down the potential of electric energy received from transmission lines via receptacle 402. Moreover, if a potential of electric energy received via receptacle 402 is predetermined, selector 314, which selects the potential of input electric energy, may be omitted.

To guard against contact with receptacle 402 and the bare transmission line ends inserted therein, a cover (not shown) in system 400 may selectively close over receptacle 402 to secure the transmission line ends in place and guard against the risk of exposure. Moreover, to increase stability, a base 404 made of a heavy and/or strong material, such as concrete, may be provided on a bottom end of system 400 to secure system 400. Furthermore, system 400 may include materials that provide aesthetic appeal and/or camouflage for use in an outdoor environment. For example, system 400 may include an artificial rock having an opening or recess for housing the components of system 400.

### V. Fifth Embodiment

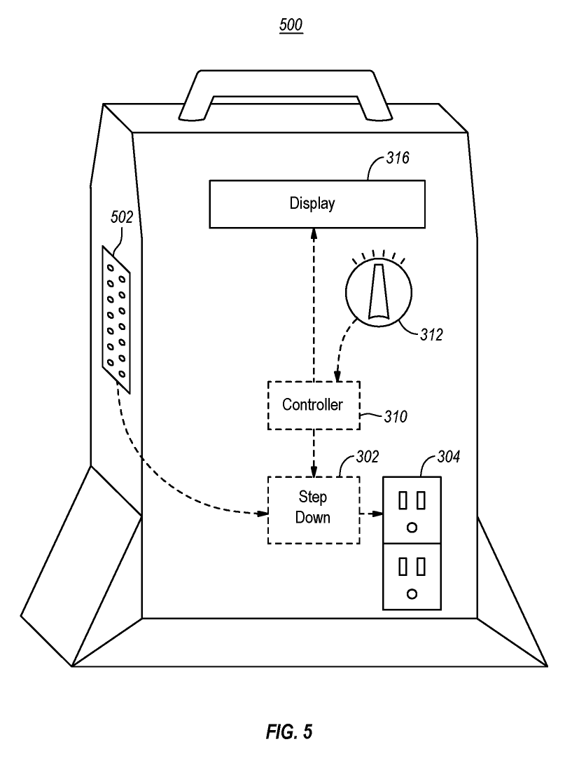

FIG. 5 shows another system 500 that may be used instead of or in addition to systems 300 and 400. System 500 is similar to system 400 but includes a plurality of receptacles 502, each being configured to receive a transmission line carrying electric energy of a different potential. Step-down transformer 302 may also have a plurality of corresponding inputs. For example, an input winding of step-down transformer 302 may have a plurality of tap-in points that function as inputs corresponding to each receptacle 502 so that a number of turns in the input winding depends on the tap-in point used as an input. Accordingly, an amount by which step-down transformer 302 steps down the potential of received electric energy depends on which receptacle 502 receives the electric energy. In this manner, an operator can select which receptacle 502 to use depending on the potential of the received electric energy and thereby select a level by which step-down transformer 302 steps down the potential of the received electric energy. To aid the operator in selecting which receptacle 502 to use, each receptacle 502 may have a corresponding potential level posted nearby. Because the potential of the received electric energy is selected by which receptacle 502 is used to receive the electric energy, selector 314, which selects the potential of input electric energy, may be omitted.

In an alternative embodiment of system 500, controller 310 may receive an indication of which receptacle 502 receives the input electric energy and may control step-down transformer 302 accordingly to step down the input electric energy by an appropriate amount. Moreover, both embodiments of system 500 may include a protective cover (not shown) that covers receptacles 502 for safety.

### VI. Sixth Embodiment

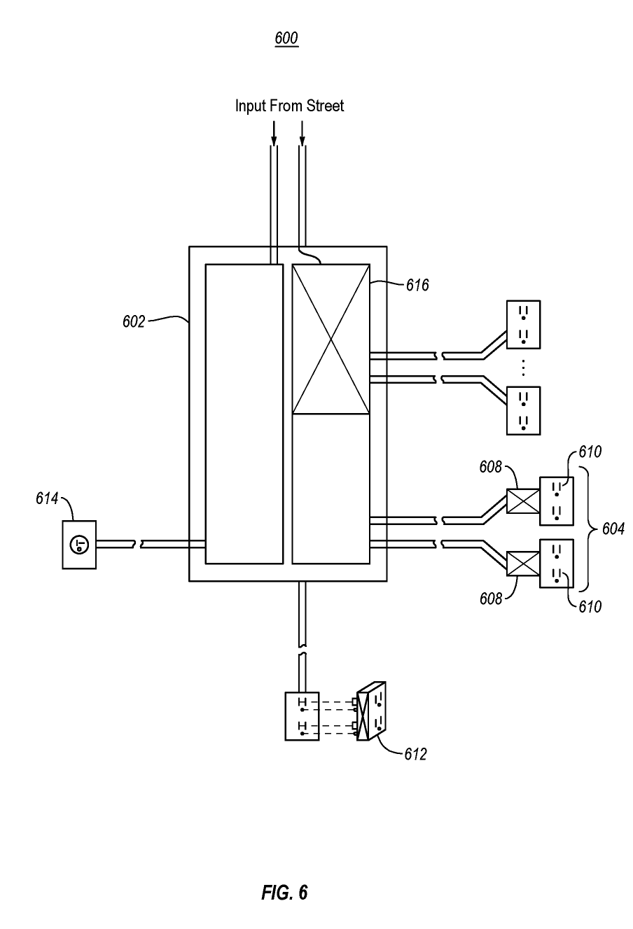

FIG. 6 depicts a system 600 including an electric distribution panel 602 located in a building, such as a home, office, or commercial space, that receives high potential (e.g., 240 to 300 volt) electric energy from an external source and supplies the high potential electric energy without stepping it down to one or more electric sockets 604 or other electric junctions or switches, such as a lighting fixture, in the same building. Distribution panel 602 may be located in a basement or other out of the way location in the building. Moreover, distribution panel 602 may receive and distribute electric energy from a public-use power grid, e.g., through a step-down transformer on a street adjacent to the building. The step-down transformer on the street may be modified to provide electric energy at a higher potential level than would normally be used. Furthermore, distribution panel 602 may distribute the received electric energy over a plurality of circuits and distribution panel 602 may include a circuit breaker for each circuit.

A step-down transformer 608 may be located at or very near step-down electric sockets 604 to step down the high potential electric energy to a useable level (e.g., 110 volts). Accordingly, the electric energy is transmitted from distribution panel 602 at a high potential to reduce loss over the transmission lines between distribution panel 602 and the point of electric energy consumption.

Step-down electric sockets 604 may be similar to and may replace standard electric sockets. Each of step-down electric sockets 604 may differ from standard electric sockets in that each includes a step-down transformer 608 integrated with or selectively attached on a side thereof. Step-down transformer 608 may be positioned so that when the socket is installed, e.g., in a wall, step-down transformer 608 is hidden or covered by the wall. Each of step-down electric sockets 604 includes a receptacle (not shown) that receives a transmission line originating from electric distribution panel 602, as shown. Step-down transformer 608 is coupled to receive electric energy over the transmission line and configured to step down a potential of the received electric energy. Each step-down electric socket 604 may include a plug interface 610 configured to supply the stepped-down electric energy to an electric machine when a plug of the electric machine is inserted into the plug interface.

As an alternative to or in addition to replacing standard sockets with step-down electric sockets 604, system 600 may also include plug-in step-down transformers 612. Plug-in step-down transformers 612 may simply plug into existing electric sockets that are not equipped with step-down transformers and may provide the potential step-down function.

A high potential socket 614 with a special-use keying may also be coupled to electric distribution panel 602 to receive the high potential electric energy and supply it to, e.g., system 300 of FIG. 3, which steps the electric energy potential down closer to a location at which the electric energy is consumed. High potential socket 614 may be located, for example, on an exterior wall of the building to facilitate access by system 300 in an outdoor environment.

In one embodiment, electric distribution panel 602 also includes a step-down transformer 616 that provides stepped-down electric energy to any sockets or other junction boxes that are within a relatively small distance from distribution panel 602. Including step-down transformer 616 at electric distribution panel 602 would beneficial particularly when the costs of adding step-down transformers 608 at the relatively close sockets or junction boxes, which do not provide as much energy savings as the more distant step-down transformers, is greater than the cost of the single step-down transformer 616.

Step-down transformer 616 may include multiple outputs or transformer taps, each providing electric energy at a different potential level (e.g., 600 volts, 300 volts, 200 volts, etc). Moreover, system 600 may include a circuit breaker for each output of step-down transformer 616 to guard against excessive loads. By providing a variety of potential levels, distribution panel 602 may be customized to provide electric energy over various different corresponding line lengths. For example, electric outlets, switches, and junction boxes located remotely from distribution panel 602 may be coupled to receive electric energy from step-down transformer 616 at a higher potential than locations that are closer to distribution panel 602 to maximize transmission efficiency. For safety, access to high potential outputs of step-down transformer 616 may be restricted, e.g., by lock and key, to licensed electricians.

In one embodiment, a transmission line leading from a high potential output of step-down transformer 616 (e.g., 600 or 300 volts) may efficiently transmit electric energy to a site that is remote from a main building or structure in which distribution panel 602 is located. Examples of such remote sites include a shed, well-head, garage, stable, parking lot, or the like. Moreover, another electric distribution panel may be located at the remote site to receive and step-down (if needed) the high potential electric energy for use at electric sockets and/or electric junctions or switches, such as lighting fixtures, located at the remote site.

System 600 is just one example of how the existing wiring, or wiring for new construction, of a home or other building can easily be utilized for the transmission of a higher potential to be received at one or more electric sockets, switches, and/or junction boxes. Moreover, instead of locating step-down transformers at electric sockets, switches, or junction boxes, a step-down transformer may be located at a strategic position, such as at a room that consumes large amounts of electric energy and each electric socket, switch, or junction box in the room may be supplied with stepped-down electric energy from the strategically located step-down transformer.

### VII. Example Methods

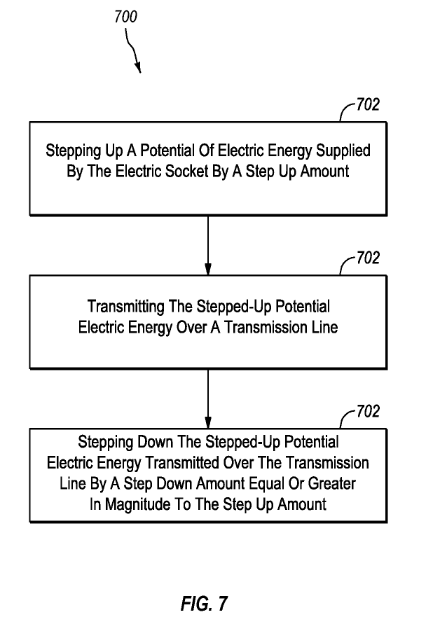

FIG. 7 shows an example method 700 for providing electric energy from an electric socket to an electric machine (also called “electric device” herein). Method 700 includes a first stage 702 in which a potential of electric energy supplied by an electric socket is stepped up by a step up amount. Next, at stage 704, the stepped-up potential electric energy is transmitted over a transmission line. Finally, at stage 706, the stepped-up potential electric energy transmitted over the transmission line is stepped down by a step down amount. A magnitude of the step up amount is the same as or greater than a magnitude of the step down amount.

Method 700 may be implemented using extension cord 100 of FIG. 1. For example, step-up transformer 104 may be used to carry out stage 702, transmission line 106 may be used to carry out stage 704, and step-down transformer 108 may be used to carry out stage 706.

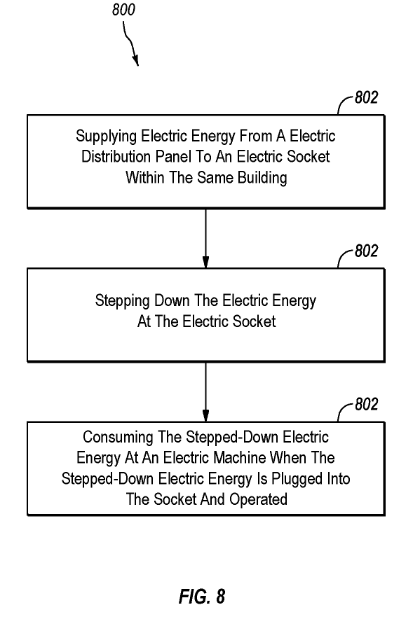

FIG. 8 shows an example method 800 for providing electric energy from an electric distribution panel to an electric machine. At a first stage 802 of method 800, electric energy is supplied from an electric distribution panel to an electric socket. Both the electric distribution panel and the electric socket are located at the same building. The electric energy is stepped down at the electric socket, at stage 804. Then, at stage 806, the stepped-down electric energy is consumed at an electric machine when the stepped-down electric energy is plugged into the socket and operated.

System 600 of FIG. 6 may be used to implement method 800. For example, electric distribution panel 602 may be used to carry stage 802 and one or more of step-down transformers 608 and/or 612 may be used to carry out stage 804. In addition or alternatively, step-down transformer 302 of system 300, which may be coupled to high potential socket 614, may be used to carry out stage 804. An electric machine (not shown in system 600) may be used to carry out stage 806.

The order of stages shown in example methods 700 and 800 may differ from that shown. Moreover, one or both of example methods 700 and 800 may omit one or more stages and/or include one or more additional stages.

The foregoing detailed description of various embodiments is provided by way of example and not limitation. Accordingly, the present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

1-20. (canceled)

21. A portable system for receiving electric energy over a distance and distributing the received electric energy, the system comprising:
a housing, the housing being sized such that the housing is moveable by a human end user of the portable system;
a handle attached to the housing to allow for the human end user to move the housing;
a transmission line having a first end that is external to the housing and that is coupled to an external energy source that provides electric energy at a level that allows the electric energy to be transmitted from the energy source but that is not useable by devices of the human end user without down conversion, the first end of the transmission line being coupled to the external energy source at a point where the electric energy is stepped down by a step down source that is not associated with the transmission line, the first end being configured to receive the electric energy from the external energy source at the level that the electric energy is provided to the step down source that is not associated with the transmission line;
a step-down transformer coupled to a second end of the transmission line that is coupled to the housing so as to receive the electric energy from the external source as the energy is transmitted by the transmission line and configured to step down a potential of the electric energy to a level that is useable by the devices of the human end user;
an electric socket implemented in the housing and configured to receive the stepped-down electric energy and to supply the stepped-down electric energy to a plug of one or more of the devices of the human end user when the plug is mated with the electric socket; and
a variable display configured to receive input from the human end user and to display diagnostic output for the human end user.

22. The system of claim 21, further comprising an electric energy receptacle configured to receive the electric energy from the external source by being coupled to the second end of the transmission line and to supply the electric energy to the step-down transformer.

23. The system of claim 21, wherein the variable display is coupled to a controller and configured to receive input from the human end user regarding the potential level of the electric energy received from the external source.

24. The system of claim 23, wherein the variable display is further configured to receive input from the human end user regarding a length of a second transmission line over which the stepped-down electric energy is to be transmitted from the system.

25. The system of claim 21, wherein the variable display includes a manually controllable selector.

26. The system of claim 21, further comprising a plurality of electric energy receptacles, each of the plurality of electric energy receptacles configured to receive a transmission line from the external source and to supply the electric energy from the transmission lines to the step-down transformer.

27. The system of claim 21, wherein the system includes a generator unconnected to any public-use power grid and configured to generate electric energy at a potential that is higher than a potential supplied by a power company to a wall socket, wherein the generator is the external source; and
wherein the transmission line is coupled to receive the high potential electric energy from the generator and configured to convey the high potential electric energy over a distance to the step-down transformer.

28. The system of claim 27, wherein the generator is configured to generate the electric energy using at least one of wind, water, solar energy, a petroleum product, and a nuclear reaction.

29. The system of claim 28, wherein the generator includes a transformer configured to step up a potential of the generated electric energy.

30. The system of claim 1, further comprising:
a controller configured to control a step-down amount of the step-down transformer based at least in part on the level of the electric energy received from the external source via the transmission line, the level of the electric energy received from the external source based at least partially on the length of the transmission line, and
the controller configured to control a step-down amount of the step-down transformer based at least in part on a length over which the stepped-down electric energy is to be transmitted via a second transmission line associated with the one or more devices of the end user such that the potential of the electric energy at a remote end of the second transmission line over which the stepped-down electric energy is to be transmitted from the system is at the level that is useable by the one or more of the devices of the end user, the controller configured to determine an optimum length of the second transmission line.

31. The system of claim 21, wherein the variable display includes one or more instructions or formulas that specify to the human end user the length the transmission line should be to achieve desired result.

32. The system of claim 31, wherein the one or more instructions or formulas also specify a length of a second transmission line over which the stepped-down electric energy is to be transmitted from the system.
